(19) United States
(12) Patent Application Publication
(10) Pub. No.: US 2026/0290089 A1
(43) Pub. Date: Sep. 24, 2026

(54) SYSTEM AND METHOD FOR DETERMINING VEHICLE BATTERY HEALTH STATUS

(71) Applicant: Innova Electronics Corporation, Irvine, CA (US)

(72) Inventors: Phuong Pham, Fountain Valley, CA (US); Ly Bach, Ho Chi Minh City (VN); Tai Mai, Ho Chi Minh City (VN); Hoang Nguyen, Dinh Quan District (VN)

(21) Appl. No.: 19/038,429

(22) Filed: Jan. 27, 2025

(51) Int. Cl. G07C 5/08; B60R 16/033; G01R 31/392

(52) U.S. Cl. CPC G07C 5/0808; G01R 31/392; B60R 16/033

(57) ABSTRACT

A method of determining a battery health status of a vehicle battery includes obtaining a battery tester result of a battery test performed on the vehicle battery using a battery tester, determining a stored/pending status of one or more OBD-II diagnostic trouble codes (DTCs), determining whether the vehicle exhibits out of range OBD-II live data in response to one or more OBD-II live data requests, and determining the battery health status based on the battery test result, the stored/pending status of the one or more OBD-II DTCs, and an outcome of determining whether the vehicle exhibits out of range OBD-II live data. The method may further include determining a stored/pending status of one or more OEM DTCs and/or whether the vehicle exhibits out of range OEM live data, with the battery health status being further based on these results.

### CROSS-REFERENCE TO RELATED APPLICATIONS

This application is a continuation-in-part of co-pending U.S. patent application Ser. No. 18/137,753, filed on Apr. 21, 2023, the contents of which are incorporated herein by reference.

### STATEMENT RE: FEDERALLY SPONSORED RESEARCH/DEVELOPMENT

Not Applicable

### BACKGROUND

A car battery is a rechargeable power source that provides the electrical energy necessary for starting a vehicle's engine or powering its electric motors, depending on whether the vehicle uses an internal combustion engine (ICE) or is an electric vehicle (EV). In traditional ICE vehicles, the battery delivers a high surge of current to the starter motor, enabling the engine to ignite, while also powering essential systems like lights, infotainment, and climate controls. In EVs, the battery is typically a larger unit that stores and supplies energy to drive the electric motor, enabling propulsion and running all onboard electronics. Regardless of the type, the battery works in conjunction with other systems, such as the alternator in ICE vehicles or regenerative braking in EVs, to recharge itself and maintain sufficient energy for continued use.

Car batteries rely on different technologies to provide the power needed for starting engines, running electrical systems, and, in the case of electric or hybrid vehicles, powering electric motors. One of the oldest and most common technologies is lead-acid batteries. These are known for their reliability and ability to deliver a high current for starting engines. They are categorized into different types such as flooded lead-acid batteries, which have liquid electrolytes and require maintenance, and sealed or valve-regulated lead-acid batteries, which include absorbent glass mat (AGM) and gel batteries. AGM batteries use a fiberglass mat to absorb electrolytes, making them spill-proof and maintenance-free, while gel batteries contain a gel-like electrolyte that provides good deep-cycle performance and spill resistance.

Another technology is lithium-ion batteries, which are widely used in electric and hybrid vehicles due to their high energy density, lightweight construction, and longer lifespan compared to lead-acid batteries. Lithium-ion batteries come in several chemistries, each with specific advantages. For example, lithium iron phosphate (LiFePO₄) batteries are known for their stability and long cycle life, while lithium nickel manganese cobalt oxide (NMC) batteries are popular in passenger electric vehicles for their good balance of energy density and safety. Other chemistries like lithium nickel cobalt aluminum oxide (NCA) offer high energy density for performance-oriented vehicles, while lithium manganese oxide (LMO) batteries are valued for their thermal stability.

Nickel-metal hydride (NiMH) batteries are commonly used in hybrid vehicles. They offer decent energy density, reliability, and are more environmentally friendly than older technologies, although they are heavier and less energy-dense compared to lithium-ion batteries. Many hybrids are now transitioning to lithium-ion batteries for better performance.

Emerging technologies include solid-state batteries, which replace liquid or gel electrolytes with a solid material, offering the potential for higher energy density, improved safety, and longer lifespan. Although still in development, solid-state batteries are seen as a promising future technology for electric vehicles. Another developing technology is lithium-sulfur batteries, which use sulfur as a cathode material and have the potential to be lighter and more efficient, although issues with lifespan and stability remain to be solved.

Zinc-air batteries use zinc as an anode and oxygen from the air as a cathode, offering high energy density and environmental friendliness. Although not yet widely adopted in vehicles, they have potential applications in electric vehicles due to their cost-effectiveness. However, limitations in power output and recharging technology need to be addressed before they become viable.

Ultracapacitors, while not technically batteries, are sometimes used alongside battery packs in electric or hybrid vehicles. They are capable of quickly storing and releasing energy, making them useful for applications like regenerative braking and providing bursts of power for acceleration. Ultracapacitors help improve efficiency and extend battery life by working in conjunction with conventional battery systems.

Car batteries can fail in several ways, each stemming from different causes and resulting in various symptoms. One common failure mode is sulfation, which occurs primarily in lead-acid batteries when they are left in a discharged state for too long. Sulfation involves the buildup of lead sulfate crystals on the battery's plates, reducing its ability to accept a charge and deliver power, eventually leading to a loss of capacity and failure to start the vehicle. Corrosion is another issue, where battery terminals and connections degrade over time due to acid leaks, creating resistance in the electrical path and leading to voltage drops, poor starting performance, and electrical problems. Internal short circuits can also occur if the separators between battery plates become damaged, allowing the plates to touch and causing rapid self-discharge, excessive heat, or a complete inability to hold a charge. This often results in sudden failure.

Parasitic drain happens when electrical components continue to draw current from the battery even when the car is turned off, slowly discharging the battery over time. Improperly functioning lights, sensors, or infotainment systems are common causes of parasitic drain, which can leave the battery unable to start the vehicle. Overcharging, another mode of failure, occurs when the vehicle's alternator or an external charger supplies voltage above the recommended level, leading to overheating and loss of water through evaporation, damaging the battery plates and reducing its lifespan. On the other hand, undercharging occurs when the battery isn't supplied with sufficient voltage to fully recharge, often due to a malfunctioning alternator or short trips that don't allow enough time to replenish the battery. Persistent undercharging leads to sulfation and capacity loss.

Physical damage is another factor that can lead to battery failure. Impacts or severe vibrations can crack the battery casing or dislodge the internal plates, causing leaks, short circuits, or diminished performance. Batteries are also vulnerable to thermal degradation from extreme temperatures. High temperatures accelerate electrolyte evaporation in lead-acid batteries, reducing their lifespan, while cold temperatures slow down the battery's chemical reactions, making it harder to start the engine. Repeated exposure to these conditions weakens the battery's overall performance. Finally, aging and capacity loss occur naturally over time due to repeated charge and discharge cycles. Lead-acid batteries experience gradual sulfation and weakening of the plates, while lithium-ion batteries lose active material that holds and releases energy, reducing their capacity to store and deliver energy.

These failure modes often manifest as difficulty starting the vehicle, dimming lights, or error messages from the vehicle's electrical systems. Recognizing these symptoms and understanding the underlying causes can help determine whether the battery needs maintenance, replacement, or repairs to the vehicle's electrical or charging systems. Battery problems can be diagnosed with the use of battery testers.

Car battery testers originated alongside the development of automobiles in the early 1900s, when car batteries were primarily used to power electric starters, lights, and ignition systems. The widespread adoption of lead-acid batteries, first introduced in 1859, made battery maintenance crucial for automotive reliability. Initially, battery testing was a rudimentary process. Mechanics manually inspected batteries for physical issues like leaks or corrosion, and they used generic electrical tools like voltmeters to check battery voltage. These basic methods persisted through the early days of automobile maintenance.

As automotive electrical systems grew more complex, especially with the introduction of alternators in the 1950s, the need for dedicated battery testers emerged. Early dedicated testers included hydrometers, which measured the specific gravity of the electrolyte in lead-acid batteries, indirectly indicating the battery's charge level. Voltmeters, which had previously been general tools, also became more specialized for car battery testing, but they could only measure the battery's open-circuit voltage, lacking the ability to evaluate the battery's performance under load.

By the 1970s, load testers were introduced, modernizing battery diagnostics. These devices simulated the electrical demands a car places on a battery, measuring its ability to maintain voltage under load. Manual load testers became a standard tool in repair shops, allowing mechanics to assess whether a battery could meet the demands of a vehicle's starting system. This type of testing marked a significant improvement over previous methods, which only measured static voltage levels.

In the 1990s, digital technology transformed battery testers, making them more precise and user-friendly. Digital load testers and voltmeters replaced analog versions, and they could quickly measure voltage, current, and resistance. The introduction of conductance testers around this time allowed for non-invasive testing by measuring a battery's electrical conductance. These testers were more advanced because they could assess the battery's internal resistance and overall health without placing stress on the battery.

As cars became more complex in the 21st century, particularly with the introduction of start-stop systems, hybrid powertrains, and electric vehicles, battery testers evolved to include multi-function diagnostic capabilities. Modern testers now evaluate not only the battery but also the car's charging and starting systems, diagnosing issues with the alternator, starter motor, and the battery itself. Some testers now feature wireless connectivity, enabling real-time monitoring and data storage via smartphones or computers.

Electric vehicles and hybrids introduced new challenges for battery testing. While traditional lead-acid batteries are still tested in the same manner, the high-voltage lithium-ion batteries used in electric vehicles are monitored by battery management systems (BMS), which ensure individual cells within the battery pack are functioning optimally. These BMS systems are integral to the overall health and safety of modern electric vehicle batteries.

Car battery testers can fail in various ways, often due to issues with their components or misuse. One common way they can fail is through faulty internal circuitry. Battery testers rely on precise electronic circuits to measure voltage, current, and resistance. If these internal circuits become damaged due to exposure to moisture, physical impact, or manufacturing defects, the readings can become inaccurate or the tester might stop functioning altogether. Damage to circuits can result in unreliable measurements, leading users to misjudge the health of a battery.

Another failure mode is sensor degradation. Many modern battery testers use sensors to measure parameters like conductance or temperature. Over time, these sensors can wear out or lose calibration, particularly if the tester is used frequently or exposed to harsh conditions. Sensor degradation can cause the tester to give inconsistent results or to misread key battery characteristics like voltage and internal resistance.

Poor quality connections in the tester's clamps or cables are another common failure point. The clamps are the key interface between the tester and the battery, and if they become loose, corroded, or damaged, the tester may not get a solid connection with the battery terminals. This can lead to intermittent readings or false low-voltage warnings, causing confusion and misdiagnosis. Over time, frequent use and exposure to corrosive battery acids can degrade the quality of these connections, leading to tester failure.

In addition, software errors in digital battery testers can lead to incorrect readings. Many modern testers rely on software to interpret the data gathered from the battery and present it in a readable format. If the software has bugs or becomes corrupted, the tester might display erroneous information or fail to operate correctly. Sometimes, software updates or faulty firmware can also introduce errors, especially in advanced testers that measure and analyze multiple parameters.

Battery depletion or power failure is another straightforward but impactful cause of tester malfunction. Many battery testers rely on internal batteries to operate their display and measurement circuits. If the tester's internal battery is weak or dead, it can give false readings or fail to power on. This issue is particularly common in testers that are used infrequently or not stored properly, causing their batteries to drain over time.

Physical wear and tear can also lead to tester failures. Dropping the tester, exposing it to high humidity, or allowing it to accumulate dirt can all damage sensitive internal components or create shorts. Cracked screens, damaged buttons, or broken enclosures are common outcomes that can render the tester difficult or impossible to use effectively. The more often a tester is exposed to rough handling, the greater the likelihood of these types of failures.

Lastly, misuse or incorrect operation by users can also cause a battery tester to fail. Connecting the tester to a battery with the wrong polarity, trying to test a battery outside the device's voltage range, or using the tester in extreme conditions like very high or low temperatures can damage the device. Overloading a tester by connecting it to a battery with an unexpected surge of current can also harm its circuits.

A faulty battery tester poses several risks and dangers that can impact both the user and the vehicle. One of the primary risks is the possibility of incorrect diagnostic readings, which can lead to misjudging the condition of a car's battery. If a faulty tester inaccurately reports a healthy battery as failing, users may replace a perfectly functional battery, resulting in unnecessary expenses and wasted time. Conversely, if the tester incorrectly indicates that a failing battery is in good condition, the vehicle could experience unexpected breakdowns, leaving the driver stranded and in potentially unsafe situations.

A significant danger is the potential for electrical hazards. Faulty testers, particularly those with damaged wiring, poor insulation, or malfunctioning internal circuits, can cause short circuits or sparks when connected to a battery. This risk is amplified by the fact that car batteries contain significant electrical power and can release it quickly if not handled properly. A spark or short circuit near a car battery can lead to burns, electrical shocks, or even battery explosions in extreme cases.

Another risk is damage to the vehicle's electrical system. A malfunctioning tester that improperly draws excessive current or creates a reverse polarity connection can potentially harm the car's electrical components, such as the alternator, sensors, or electronic control units. Such damage can lead to costly repairs and impair the vehicle's performance and safety features.

There is also the possibility of battery overloading or overheating. If a faulty tester fails to measure internal resistance accurately or misreads voltage levels, it may give a false impression of a battery's capacity to hold a charge or deliver current. This could result in the battery being overused or left in a charged state longer than necessary, leading to overheating or accelerated wear. In some cases, this could lead to battery leaks or, in extreme cases, thermal runaway, where the battery becomes dangerously hot and potentially catches fire or explodes.

Additionally, a faulty tester can give inconsistent or fluctuating readings, causing confusion for the user. Inexperienced users may not realize the tester is defective and could take actions based on conflicting information, such as performing unnecessary jump starts or overcharging the battery. This could not only harm the battery but also create potential risks in handling or operating the vehicle.

Finally, physical injury is a risk if the faulty tester causes the battery to release harmful gases or electrolyte spills. Lead-acid batteries emit hydrogen gas, which is highly flammable, and an accidental spark from a faulty tester could ignite the gas, causing an explosion. Furthermore, if a battery leaks due to being mishandled by a malfunctioning tester, the acidic electrolyte can cause chemical burns to the skin or eyes.

In summary, the dangers of a faulty battery tester include inaccurate readings that can lead to unexpected breakdowns or unnecessary replacements, risks of electrical hazards like shocks or sparks, potential damage to a vehicle's electrical systems, battery overloading or overheating, confusion from inconsistent readings, and physical injury from battery explosions or spills.

### BRIEF SUMMARY

The subject disclosure provides a comprehensive method, computer program, and system for determining the health status of a vehicle battery by combining results from a battery test with diagnostic information retrieved from the vehicle's onboard diagnostic system (OBDS). An example embodiment starts with obtaining a battery test result, such as a measurement of cold cranking amps (CCA), using a battery tester. The system then checks the OBDS for stored or pending diagnostic codes that are related to faults in critical circuits such as the battery temperature sensor circuit, generator control circuit, generator lamp circuit, generator field terminal circuit, generator voltage sensing circuit, generator system performance, or charging system voltage regulation.

Example embodiments determine whether live data received from the OBDS indicates that certain values are out of their normal ranges. The system monitors key data points like control module voltage and alternator load percentage. If these data points are outside expected thresholds, this indicates a potential issue with the battery or charging system. The results from these checks are then combined to establish the overall battery health status, indicating whether the battery is in a passing condition or if there are issues that require attention.

Example embodiments incorporate additional checks on manufacturer-specific (OEM) diagnostic codes and data. This involves determining whether there are any stored or pending OEM diagnostic codes, which are based on the vehicle identification number (VIN). The system can also analyze OEM-specific live data to identify out-of-range values related to vehicle-specific components and configurations. This additional analysis provides a deeper level of insight into the health of the vehicle's battery and charging system.

Example embodiments includes use of a machine learning model to process the battery test result, stored or pending OBDS and OEM diagnostic codes, and out-of-range OBDS and OEM live data. This model helps identify patterns and trends, improving the accuracy of battery health assessments and predictions of potential failures. The machine learning model is particularly useful for interpreting complex interactions between multiple diagnostic codes and live data points.

An example embodiment of a computer program product includes one or more non-transitory program storage medium containing executable instructions. These instructions direct processors or programmable circuits to perform operations such as obtaining the battery test result, checking for OBDS diagnostic codes, analyzing OBDS live data, and incorporating additional checks for OEM diagnostic codes and live data based on the vehicle's Vehicle Identification Number (VIN).

Example embodiments for determining battery health includes a battery tester that performs the initial battery test and one or more servers that are configured to receive the battery tester result. The servers also determine the status of stored or pending OBDS diagnostic codes and whether live data is out of range. The servers use this information, combined with additional checks for OEM diagnostic codes and live data, to determine the battery health status. The system can include a diagnostic tool that retrieves OBDS diagnostic codes and live data from the vehicle, which it then wirelessly transmits to the servers. This tool can communicate with the servers via a mobile device connection or through a short-range wireless link.

The diagnostic tool and servers work together to create a complete picture of the battery's health status. This approach ensures that the method is thorough, combining standard battery tests with vehicle-specific diagnostic data to provide a reliable and accurate assessment of the battery's condition. The invention allows for real-time monitoring and analysis, helping predict battery failures and enabling proactive maintenance.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 shows a system for determining a battery health status of a vehicle battery according to an embodiment of the present disclosure;

FIG. 2 shows a flowchart of an example embodiment of a procedure for determining the battery health status of the vehicle battery;

FIG. 3 shows a flow diagram corresponding to the flowchart of FIG. 2;

FIGS. 4A and 4B show a flowchart of another example embodiment of a system for determining battery health status;

FIG. 5 shows example diagnostic testing codes to be applied to a first battery health test;

FIG. 6 shows example pending diagnostic testing codes to be applied to the first battery health test;

FIG. 7 shows example onboard diagnostic live data to be applied to a second battery health test;

FIG. 8 shows example OEM diagnostic testing coeds to be applied to a third battery health test;

FIG. 9 shows example OEM history diagnostic testing codes to be applied to the third battery health test; and FIG. 10 shows example OEM live data to be applied to a fourth battery health test.

### DETAILED DESCRIPTION

The present disclosure encompasses various embodiments of systems, methods, and devices for use in determining a vehicle battery health status. The detailed description set forth below in connection with the appended drawings is intended as a description of several currently contemplated embodiments and is not intended to represent the only form in which the disclosed invention may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

Vehicle On-Board Diagnostic Systems (OBDs) are electronic systems in vehicles that monitor and regulate various engine and emission control components to ensure optimal performance and compliance with environmental standards. Originally developed in the 1980s, OBD systems were designed to help technicians diagnose issues by providing access to information from the vehicle's control modules. OBD-I (On-Board Diagnostics I) was a first generation OBD system implemented in vehicles. It was introduced primarily in the 1980s and became mandatory in the United States in 1991 by the California Air Resources Board (CARB) to monitor and control vehicle emissions. However, OBD-I was not a unified or fully standardized system in the way that OBD-II is today. The introduction of the OBD-II standard in 1996 in the United States made it mandatory for all cars to have a universal diagnostic system that could communicate standardized codes, known as Diagnostic Trouble Codes (DTCs), to identify specific malfunctions. OBD systems monitor the engine, transmission, emissions controls, and other crucial systems, and they can alert the driver with a “Check Engine” or similar warning light when a fault is detected. This technology allows mechanics and vehicle owners to diagnose and address problems quickly using an OBD scanner, improving vehicle reliability, safety, and environmental performance.

The terms DTC OBD-II data, OBD-II live data, DTC OEM data, and OEM live data refer to different types of vehicle diagnostics information that can be accessed through a car's OBD system. Each term represents a different layer of data or diagnostic information, and they vary in the level of detail, accessibility, and specificity to particular manufacturers. Here's an explanation of each:

DTC OBD-II data refers to DTCs generated and stored by a vehicle's OBD-II system. OBD-II live data refers to a wider range of information that the OBD-II system provides, which includes not just DTCs but also live data and freeze-frame data about how the car's various systems are performing. Live data offers real-time information like engine RPM, coolant temperature, and oxygen sensor readings, while freeze-frame data is a snapshot of the vehicle's operating conditions at the moment a DTC is triggered. This gives technicians valuable context to diagnose the problem more accurately. Like DTCs, OBD-II live data is standardized and can be accessed with most OBD-II scanners.

DTC OEM data is similar to DTC OBD-II data but is specific to the vehicle's manufacturer, known as the Original Equipment Manufacturer (OEM). These are manufacturer-specific codes that provide more detailed diagnostic information beyond the standardized OBD-II codes. While OBD-II codes might flag a general issue like a misfire, an OEM-specific code could give more in-depth information about what's wrong with a system unique to that particular brand or model. Accessing these codes often requires specialized tools that are compatible with the manufacturer's diagnostic system.

OEM-specific DTCs often share common prefixes with standard DTCs when they address similar systems or areas of the vehicle, but they are differentiated by the codes that follow the prefix. Standard OBD-II DTCs follow a specific format defined by the Society of Automotive Engineers (SAE) in the United States, which uses a letter followed by four digits (e.g., P0XXX), where:
P refers to the Powertrain (engine, transmission, and associated components).
B refers to the Body (interior and exterior functions).
C refers to the Chassis (suspension, steering, etc.).
U refers to Network Communication (data transmission between different modules).

For standard DTCs, a “0” in the second digit (e.g., P0XXX) indicates that the code is generic and standardized across all manufacturers. However, if the second digit is a “1” (e.g., P1XXX), it indicates that the DTC is manufacturer-specific (OEM DTC).

OEM live data covers a broader range of information specific to a vehicle's manufacturer and goes beyond standard OBD-II diagnostics. This data includes everything from manufacturer-specific system data for things like airbags or infotainment systems to proprietary live data from systems that are unique to the car, such as safety features, climate control, or hybrid powertrain systems. It may also involve advanced diagnostics, programming, or control of these systems. To access OEM live data, one usually needs specialized diagnostic equipment designed for the specific vehicle brand, as this data isn't typically available through standard OBD-II scanners. Extraction of OEM live data is suitably accomplished by determining a Vehicle Identification Number (VIN), which number can be obtained from a vehicle OBD port.

A VIN is a unique 17-character code assigned to every vehicle, acting as a universal identifier. This code contains standardized and sometimes manufacturer-specific information that helps identify various attributes of a vehicle. The VIN is structured into three main sections: World Manufacturer Identifier (WMI), Vehicle Descriptor Section (VDS), and Vehicle Identification Section (VIS).

The first three characters of the VIN represent the WMI. These characters identify the vehicle's manufacturer, country of origin, and sometimes the division within the manufacturer. For example, “1HG” indicates a Honda manufactured in the United States, while “JHM” specifies a Honda made in Japan. The first character signifies the country or region where the vehicle was manufactured, the second identifies the manufacturer, and the third narrows down the vehicle type or manufacturing division.

The next five to six characters make up the VDS, which provides information about the vehicle's model, body style, engine type, and transmission. This section is often standardized across manufacturers to some extent, but it may also contain manufacturer-specific codes that provide more detailed information. For instance, the VDS could reveal whether a vehicle is a sedan or a hatchback, and it might specify details like the number of doors or the engine displacement.

The final eight characters belong to the VIS, which includes a unique serial number that distinguishes each individual vehicle. In most cases, the VIS also provides details such as the model year, indicated by the tenth character, and the plant code in the eleventh character, which reveals the specific assembly plant where the vehicle was manufactured. The remaining characters in the VIS form a unique identifier that differentiates each vehicle made in a given year and plant.

In addition to this standardized information, manufacturers can encode additional details within the VIN that are specific to their vehicles. These details may include trim levels, specific engine configurations, or optional features like all-wheel drive. For example, while the VIN can indicate the engine type generally, manufacturer-specific codes within the VDS can reveal even more about the exact engine variant and its specifications.

To determine the manufacturer from the VIN, you primarily rely on the first three characters (the WMI). The first character points to the vehicle's manufacturing country or region, while the combination of the second and third characters indicates the manufacturer itself. Automotive databases or online VIN decoders can quickly reference these codes to identify the make and model of the vehicle, allowing for a determination what OEM information can be queried and obtained from the vehicle OBD port.

In summary, OBD-II live data and DTCs are standardized across all vehicles and focus mainly on engine and emissions-related systems, while OEM live data and manufacturer-specific DTCs provide more detailed information for systems unique to the car. Each serves a different diagnostic purpose, with OBD-II data offering basic information and OEM live data giving deeper insight into the vehicle's proprietary systems.

Battery health-related information obtained from an OBD system varies depending on whether it comes from DTC OBD-II data, OBD-II live data, DTC OEM data, or OEM live data. The following are examples of what each type of data can provide related to battery health:

DTC OBD-II data provides DTCs associated with battery voltage and charging issues. As used herein “associated with” refers to a predetermined relationship between a diagnostic code and a specific system, circuit, or component fault within the vehicle. This relationship is defined based on vehicle manufacturer diagnostic protocols, industry-standard guidelines such as SAE J2012, and technical service manuals that specify the connection between diagnostic trouble codes (DTCs) and the faults or conditions they indicate. A diagnostic code is considered to be associated with a fault if it is recognized in manufacturer or industry documentation as being indicative of, related to, or reflective of the operational state of the relevant system or component.

By way of example, a diagnostic code that signals a malfunction in the generator control circuit would be considered associated with that circuit based on its definition and classification under recognized automotive diagnostic standards. This association may be explicit, such as when the code is directly linked to a failure or fault in the named system, or it may be indirect when the code, although primarily related to another system, has a known impact or influence on the performance or condition of the specified system. These codes typically relate to the health and performance of the battery and charging system:
Battery Capacity Degradation (DTC P06XX)-Directly related to battery health by indicating loss of capacity.
Battery Temperature Sensor Fault (DTC P05XX)-Addresses sensor issues that could lead to improper battery thermal management.
High Battery Internal Resistance (DTC P06XX)-Indicates aging or damage within the battery.
Parasitic Drain Detection (DTC P25XX)-Focuses on abnormal current draw that could deplete the battery.
Battery Imbalance DTC (DTC P0AXX)-Identifies voltage imbalances in the battery pack, a common indicator of cell health issues.
Specific examples of battery-related OBD-II DTCs include:
P0562: System Voltage Low: Indicates that the vehicle's system voltage has dropped below a specific threshold, which may point to a failing battery or charging system issue.
P0563: System Voltage High: This code signals an overcharging condition, often due to a faulty alternator or voltage regulator, which can damage the battery.
P2503: Charging System Voltage Low: Suggests that the battery is not receiving adequate charge, likely due to a faulty alternator or voltage regulation problem.
P2504: Charging System Voltage High: Indicates an overcharging condition that could damage the battery and other electrical systems.

These codes give a general indication of battery and charging system health and are directed to basic voltage-related parameters and overcharging/undercharging situations.

OBD-II live data encompasses real-time information and DTCs accessible through the standardized OBD-II protocol. It includes a broader range of information than just DTCs. For battery health, OBD-II live data can provide:
Battery Voltage (real-time): Real-time monitoring of the battery's voltage allows for assessing the state of charge and the battery's ability to maintain voltage under various conditions.
Alternator Output: Information on the alternator's performance, which directly affects the battery's charging.
State of Charge (SOC): For some vehicles, OBD-II live data may include a basic indication of the battery's state of charge, providing insights into whether the battery is fully charged or needs recharging.

This real-time data, combined with DTCs, can help diagnose battery health and performance by showing whether the battery is consistently operating within acceptable voltage ranges.

DTC OEM data includes manufacturer-specific Diagnostic Trouble Codes that are not part of the standardized OBD-II set. These codes often provide more detailed insights into vehicle-specific systems and components. For battery health, OEM-specific DTCs may include:
Battery Temperature Sensor Faults: Codes that indicate whether the battery temperature sensor is reporting out-of-range values or has failed, which can affect charging efficiency and battery lifespan.
Battery Current Sensor Issues: DTCs related to the battery current sensor's performance, which monitors the flow of current into and out of the battery, crucial for battery health diagnostics.
Communication Loss with Battery Control Modules: DTCs indicating that the vehicle's control module has lost communication with specific sensors or systems related to the battery's monitoring.

These manufacturer-specific codes provide more in-depth information about battery-related sensors and subsystems, giving a clearer picture of the battery's health and the efficiency of its management system.

OEM live data includes comprehensive diagnostic information provided by the vehicle's Original Equipment Manufacturer (OEM). This data is not standardized and varies between manufacturers, but it typically includes advanced battery health metrics and system-specific diagnostics. Examples of battery-related information available through OEM live data include:
State of Health (SOH): The battery's overall health percentage, indicating its capacity relative to its original design. A low SOH can signal that the battery is reaching the end of its useful life.
Battery Internal Resistance: Information on the battery's internal resistance, which affects its ability to deliver current. Higher resistance can indicate aging or damage within the battery.
Battery Charge and Discharge Rates: OEM systems often provide detailed information on how quickly the battery is being charged or discharged, helping identify issues like parasitic drains or overcharging conditions.
Battery Temperature and Thermal Management Data: Detailed information about the battery's temperature and the performance of its thermal management system, which is crucial for battery safety and longevity, particularly in electric and hybrid vehicles.
Regenerative Braking Status (for hybrids and EVs): Data showing how effectively the vehicle's regenerative braking system is replenishing the battery, indicating the efficiency of the charging system.

OEM live data provides a comprehensive view of the battery's health, incorporating advanced metrics like internal resistance, state of health, and detailed charging and thermal management information. It provides insights into the battery's performance, wear level, and efficiency.

A standard battery tester typically measures key parameters like Cold Cranking Amps (CCA), drop voltage, and crank voltage to evaluate the health and performance of a car battery. The CCA measurement indicates the battery's ability to deliver a specific amount of current in cold conditions, crucial for starting the engine when temperatures are low. The measured CCA can be compared to the manufacturer's rating to see if the battery is deteriorating or still functioning effectively. Drop voltage, or voltage drop, refers to the decrease in voltage when the battery is under a heavy load, such as during the cranking of the engine. This measurement helps determine if the battery can maintain a stable voltage under demanding conditions; a significant drop often indicates a weak battery. Crank voltage, another important measurement, indicates the battery's voltage while the engine is being cranked. This is a critical measure because cranking the engine is one of the battery's most demanding tasks. A healthy battery should be able to maintain a minimum voltage during cranking, and if it falls too low, it can signal a problem.

Example embodiments herein monitor and assess car battery health by combining traditional battery measurements with vehicle diagnostic data. A battery tester is connected to the vehicle's battery to measure key parameters such as CCAs, drop voltage, and crank voltage. The system monitors and assesses car battery health by combining traditional battery measurements with vehicle diagnostic data, including standard OBD-II live data, DTC OBD-II data, DTC OEM data, and OEM live data. The system interfaces with the vehicle's OBD-II port to retrieve standard OBD-II live data, including battery voltage and charging system status, as well as DTC OBD-II data, which encompasses standardized DTCs related to battery voltage and charging issues. These DTCs help identify problems like low system voltage or overcharging.

For a more comprehensive analysis, the system also gathers DTC OEM data, which includes manufacturer-specific codes related to battery health, such as issues with battery temperature sensors, current sensors, or communication with control modules. In addition, the system collects other OEM live data that provides detailed information such as internal resistance, state of charge (SOC), state of health (SOH), and battery temperature from vehicles with advanced diagnostic systems.

The collected data is then transmitted to a cloud-based platform through wired or wireless connectivity. The cloud platform aggregates the battery measurements and diagnostic information to analyze the relationships between the different sets of data. This analysis allows the system to identify potential problems, such as a failing alternator if low CCA readings coincide with undercharging DTCs or specific OEM codes. The platform suitably uses artificial intelligence and machine learning (AI/ML) to continuously refine diagnostic and predictive models using historical data, enabling it to provide increasingly accurate assessments of battery health over time.

Users can suitably access the results through a web or mobile app that displays reports and insights. The app provides specific measurements of CCA, drop voltage, and crank voltage, while also highlighting relevant diagnostic codes from the DTC OBD-II and DTC OEM data, as well as detailed insights from the broader OBD-II and OEM live data. It offers actionable recommendations, such as suggesting battery replacement, alerting users to overcharging or undercharging problems, and flagging potential issues with sensors or the alternator. Additionally, the app keeps track of battery performance trends and sends alerts if it detects sudden drops in health.

OBD information works together with a battery tester to get a more precise understanding of how well the battery is functioning. For instance, if a DTC shows low system voltage, the tester can measure the actual CCA to confirm whether the battery has lost its capacity to deliver enough current for starting the engine. Low CCA values would indicate a weakened or failing battery.

Temperature-related DTCs, which point to issues with the battery temperature sensor, can also be cross-checked with the tester. If the sensor isn't functioning properly and the tester shows abnormal voltage drops or poor CCA performance, it suggests that improper temperature regulation is affecting the battery's performance. This may lead to overcharging or undercharging, which could shorten the battery's lifespan.

When DTCs point to problems like low battery voltage or lost communication with the battery sensor, using the tester to measure CCA and voltage under load can confirm whether the battery is still capable of meeting the vehicle's demands. If the tester shows poor CCA or significant voltage drops, this backs up the DTC's warning that the battery may need replacing. In hybrid vehicles, where DTCs might suggest problems with the battery pack, the tester's measurements of the 12V battery's performance can still help ensure that the auxiliary systems are working correctly.

Example embodiments herein accomplish battery health analysis using particular categories of DTCs. DTCs are categorized into several types, each serving a specific purpose in identifying and managing vehicle issues.

Stored DTCs are the most common type, indicating confirmed problems that the OBD system has consistently detected over time. When a stored DTC is logged, it usually triggers the “Check Engine” light on the dashboard, alerting the driver to an issue that needs attention. These codes stay in the vehicle's memory until the problem is resolved and manually cleared using a diagnostic tool or after the system automatically erases them following a series of successful drive cycles without the problem recurring.

Pending DTCs represent potential issues that the OBD system has detected but hasn't confirmed yet. These are logged when the system identifies a problem condition that doesn't yet meet the criteria for a stored DTC. Pending codes allow the system to monitor intermittent or emerging problems over time. They do not typically trigger a warning light on the dashboard. However, if the same issue is detected consistently over multiple drive cycles, the pending DTC may become a stored DTC and activate the warning light.

Permanent DTCs are another category introduced with newer OBD-II systems. These codes are designed to stay in the vehicle's memory until the OBD system confirms that the fault has been completely resolved and the vehicle passes a specific number of successful drive cycles. Permanent DTCs cannot be cleared using standard diagnostic tools. This feature helps ensure that critical issues, especially those affecting emissions, are properly addressed and not simply erased without fixing the underlying problem.

Active or Current DTCs indicate faults that are actively affecting the vehicle at the moment. These are the most pressing issues and are responsible for triggering the “Check Engine” light. Active DTCs often require immediate attention to ensure the vehicle's safety and performance.

Intermittent DTCs represent faults that occur sporadically or inconsistently. These codes are recorded when an issue is detected off and on but is not constantly present. Intermittent codes can be particularly challenging to diagnose because the problem may not always be active or easily reproducible during inspection.

While not associated with OBD-II DTCs, historic or history DTCs, sometimes referred to as history codes, can be found with OEM DTCs. History DTCs are logged as a record of issues that were previously active but are no longer present. These codes help provide a history of faults that the vehicle experienced in the past, even if those issues are not currently affecting the vehicle. Technicians use historic DTCs to understand recurring problems or to diagnose intermittent faults that may have temporarily disappeared.

For monitoring battery health, the most useful types of OBD-II DTCs are stored DTCs and pending DTCs. Stored DTCs are particularly important because they indicate confirmed issues that have consistently affected the battery or charging system. These codes, such as those indicating low system voltage or overcharging, provide direct information about whether the battery is being properly charged and maintained. Since stored DTCs stay in the vehicle's memory until the problem is resolved, they help technicians pinpoint and address issues that impact battery health. Pending DTCs are also valuable because they highlight emerging or intermittent problems that haven't been fully confirmed yet. For example, a pending code related to voltage regulation might suggest an early sign of trouble with the alternator or voltage regulator, which could affect the battery if left unchecked. Monitoring pending DTCs allows technicians to catch these potential issues early and address them before they become serious and cause lasting damage to the battery.

Permanent DTCs may also be useful because they remain in the vehicle's system until the underlying issue has been fully resolved and verified through a series of successful drive cycles. This feature is especially important for critical problems affecting the battery's charging and electrical systems. Permanent DTCs can help ensure that persistent issues, such as consistent undercharging or overcharging, are properly addressed, preventing recurring damage to the battery.

OEM DTCs for monitoring battery health may include history DTCs, in addition to stored or pending DTCs. The availability and use of history OEM DTCs over pending OEM DTCs has several advantages. Pending DTCs can show false positive results, be intermittent or be temporary, whereas history DTCs are directed to firm, documented issues.

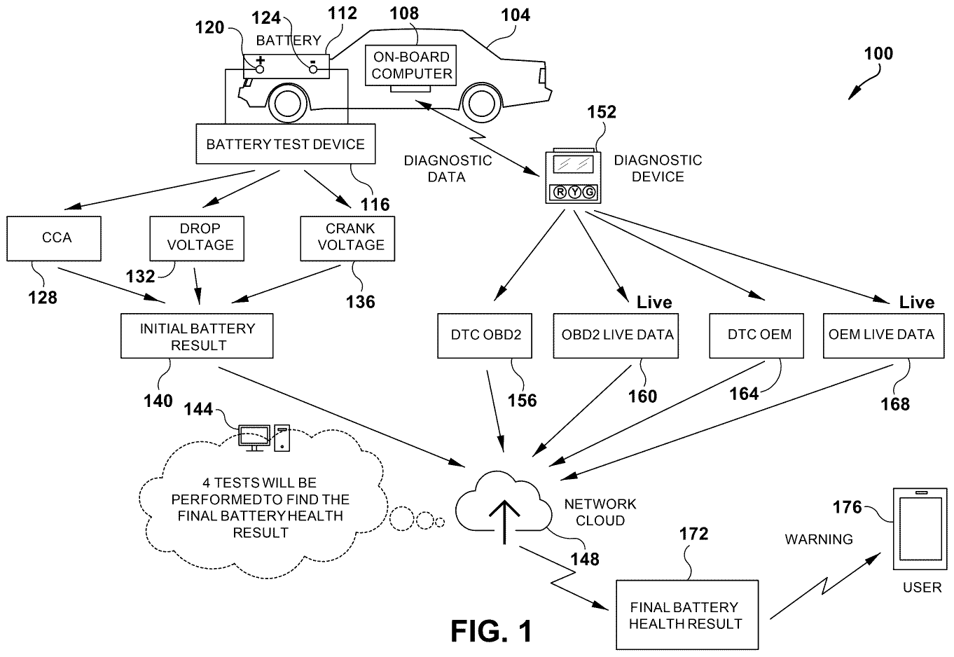

FIG. 1 illustrates a flow diagram 100 of an example embodiment of a system for determining battery health status. Vehicle 104 includes an on-board computer 108 and a battery 112. An on-board computer in a vehicle suitably comprises the entire network of electronic control units (ECUs) and central control systems that work together to manage, monitor, and coordinate various vehicle functions. It includes multiple ECUs, each responsible for specific systems such as the engine, transmission, brakes, airbags, body controls, and infotainment. In addition to these ECUs, the on-board computer typically has a central gateway module that facilitates communication between the different ECUs through a network like the Controller Area Network (CAN). The on-board computer also includes a central processor or main control unit that gathers data from the ECUs, performs diagnostics, and coordinates overall vehicle operation. This integrated system allows the on-board computer to manage key functions such as engine performance, safety systems, vehicle stability, and driver-assist features, ensuring all components work together efficiently.

Battery test device 116 is coupled to a cathode 120 and an anode 124 of battery 112 and measures cold cranking amps 128, drop voltage 132 and crank voltage 136 to generate initial battery result information 140. This initial battery result information is relayed to cloud service server 144 via network cloud 148, suitably comprised of any suitable wired or wireless data carrier in conjunction with a local area network (LAN), a wide area network (WAN), which may comprise the internet, or any suitable combination thereof.

Several vehicle control modules provide valuable battery health information. The Battery Management System is the primary module for monitoring key metrics like state of charge (SOC), state of health (SOH), voltage, temperature, and current flow, especially in hybrid and electric vehicles. The Engine Control Module (ECM) or Powertrain Control Module (PCM) tracks battery voltage and charging performance, and it can log diagnostic codes for issues like undercharging or overcharging. The Body Control Module (BCM) monitors battery voltage to detect low levels or parasitic drains when the vehicle is off. Additionally, modules like the ABS Control Module and Transmission Control Module (TCM) rely on stable battery voltage and may store fault codes if voltage issues are detected, indirectly indicating battery problems.

Vehicle information is obtained from on-board computer 108 via diagnostic device 152. Diagnostic device 152 secures vehicle data from on-board computer 108, suitably via an OBD port. A non-limiting example of a commercially available OBD-II scanner can be found in the INNOVA 5610 CarScan Pro scanner. The Innova 5610 CarScan Pro is an OBD-II diagnostic tool designed for both professional mechanics and advanced DIY users. It provides extensive diagnostic capabilities across all major vehicle systems, including the engine, transmission, anti-lock braking system (ABS), and supplemental restraint system (SRS). The tool can read and clear Diagnostic Trouble Codes (DTCs), access live data streams, and perform bidirectional control to test specific components actively.

DTC OBD-II data 156, OBD-II live data 160, DTC OEM data 164 and OEM live data 168 is suitably obtained by diagnostic device 152 by issuing one or more mode commands and one or more Parameter Identification Codes (PIDs) to on-board computer 108. Modes and PIDs are components of the OBD-II diagnostic system that allow a diagnostic testing device to communicate with a vehicle's on-board computer. Modes define the type of action or data being requested, such as retrieving real-time sensor information, stored fault codes, or vehicle details. For example, Mode 01 is used to request current data like engine RPM or battery voltage, while Mode 03 is used to retrieve stored (DTCs). Within each mode, PIDs (Parameter Identification Codes) specify the exact data point to be accessed. A diagnostic tester first selects a mode to indicate the type of information needed, and then issues a corresponding PID to obtain specific information within that mode. This combination of modes and PIDs allows the device to effectively gather targeted real-time data and diagnostic information from the vehicle's systems.

Standard modes and PIDs are defined by the OBD-II protocol (SAE J1979) and are common across all OBD-II-compliant vehicles, OEM PIDs provide additional data points specific to each vehicle manufacturer's design and architecture. These PIDs allow access to more in-depth diagnostics, monitoring, and system performance information that is unique to a particular make and model of a vehicle.

Once the manufacturer is identified through a VIN, OEM specific PIDs can be determined. Knowing the manufacturer helps identify the specific communication protocol that the vehicle uses within the OBD-II standard, such as ISO 9141-2, CAN, or SAE J1850. This understanding guides which PIDs might be relevant and accessible. The technician or diagnostic tool then suitably accesses the manufacturer's technical documentation or diagnostic software, such as Toyota's Techstream or Ford's Forscan, which contain details about the proprietary PIDs used by each brand. Diagnostic tools are suitably equipped with software modules tailored for specific manufacturers, allowing them to load the correct set of PIDs once the vehicle's VIN is recognized. These tools use extensive databases that map PIDs to each manufacturer's models and systems. Additionally, many manufacturers use Mode 22 for proprietary PIDs, and the diagnostic tool will automatically send Mode 22 requests based on the manufacturer's guidelines. Modern diagnostic systems can also adapt their queries dynamically based on the VIN, ensuring that the correct PIDs are accessed for the specific vehicle model. This approach allows the technician to retrieve the precise diagnostic data needed for that particular vehicle.

When a diagnostic tool sends a PID request to a vehicle's OBD-II system, the system responds with real-time data for that specific parameter. For example, if a PID request asks for engine RPM, the OBD-II system retrieves and sends that data from the relevant sensor. This real-time information, such as engine temperature, battery voltage, fuel pressure, and many other parameters, constitutes OBD-II live data. OBD-II PIDs are standardized, meaning they are consistent across all OBD-II-compliant vehicles, providing a common set of data points that technicians and diagnostic tools can use.

For battery health determination, specific PIDs and service modes are used to access different types of data related to battery performance, diagnostics, and monitoring. Here's a breakdown of the PIDs and modes that are relevant for obtaining DTC OBD-II data, OBD-II live data, DTC OEM data, and OEM live data specifically related to battery health:

DTC OBD-II Data (Standardized DTCs Related to Battery Health):
Mode 03 (Request Stored DTCs): Used to retrieve standard DTCs related to the battery and charging system and generator. The following DTCs are relevant for battery health:
   P0514: Battery Temperature Sensor Circuit Range/Performance
   P0515: Battery Temperature Sensor Circuit
   P0516: Battery Temperature Sensor Circuit Low
   P0517: Battery Temperature Sensor Circuit High
   P0620: Generator Control Circuit
   P0621: Generator Lamp/L Terminal Circuit
   P0622: Generator Field/F Terminal Circuit
   P0623: Generator Lamp Control Circuit
   P0625: Generator Field/F Terminal Circuit Low
   P0626: Generator Field/F Terminal Circuit High
   P063A: Generator Voltage Sense Circuit
   P063B: Generator Voltage Sense Circuit Range/Performance
   P063C: Generator Voltage Sense Circuit Low
   P063D: Generator Voltage Sense Circuit High
   P065A: Generator System Performance
   P065B: Generator Control Circuit Range/Performance
   P065C: Generator Mechanical Performance
   P0AIA: Generator Control Module
   P2500: Generator Lamp/L-Terminal Circuit Low
   P2501: Generator Lamp/L-Terminal Circuit High
   P2502: Charging System Voltage
   P2503: Charging System Voltage Low
   P2504: Charging System Voltage High
Mode 07 (Request Pending DTCs): Used to retrieve pending DTCs related to battery and charging system issues that have been detected but not yet confirmed.

OBD-II live data (Standardized Real-Time Battery-Related PIDs):
Mode 01 (Request Live Data): Used to retrieve operational parameters from various sensors and systems while the engine is running. All the PIDs listed provide real-time or status information, which falls under this mode.
   PID 42: Control Module Voltage (Battery Voltage): Reports the current voltage level of the vehicle's electrical system, which is crucial for assessing the charging system and battery health.
   PID 93: State of Charge (SOC): Indicates the current charge level of the battery as a percentage of its total capacity.
   PID 5B: Battery Current: Measures the current flowing into or out of the battery, which is essential for evaluating charging efficiency and discharge rates.
   PID 95: State of Health (SOH): Reflects the overall health of the battery, indicating how much capacity remains compared to when the battery was new.
   PID 89: Battery Internal Resistance: Provides an indication of the battery's internal resistance, which affects its ability to deliver current and can signal aging or damage.
   PID 8A: Battery Temperature: Reports the temperature of the battery, which is crucial for assessing its thermal condition and preventing overheating.
   PID 9C: Battery Cell Imbalance: Monitors the voltage differences between individual cells in the battery pack, identifying potential cell failures or imbalances.
   PID 9A: Alternator Load Percentage: Measures the load on the alternator, which can indicate how efficiently the battery is being charged.

DTC OEM Data (Manufacturer-Specific DTCs Related to Battery Health):
DTC OEM Data Mode (for example: Modes 18, 19): Used to access manufacturer-specific DTCs for more detailed issues that are not covered by standard OBD-II codes. Examples of OEM-specific DTCs for battery health include:
   Battery temperature sensor faults: Indicating issues with the temperature sensors monitoring the battery.
   Battery cell voltage imbalance: Highlighting differences in voltage between individual cells within the battery pack.
   High battery internal resistance DTC: Signaling increased internal resistance due to aging or damage in specific battery modules.

OEM live data (Manufacturer-Specific Real-Time Battery-Related PIDs):
Mode 22 (Manufacturer-Specific Data)
   Battery Cell Voltage PID: Provides real-time voltage readings for individual battery cells, which are essential for detecting imbalances or potential cell failures.
   Battery Cell Temperature PID: Monitors the temperature of individual cells or groups of cells, ensuring the battery operates within safe thermal limits.
   Battery Pack Cooling System PID: Tracks the performance of the battery cooling system, including fan speeds and coolant flow.
   Battery Pack State of Charge (SOC) PID: Provides a detailed percentage reading of the battery's current charge level, specific to the manufacturer's calibration.
   Battery Module State of Health (SOH) PID: Indicates the health of individual battery modules compared to their original capacity.
   Battery Pack Internal Resistance PID: Measures internal resistance within the battery pack, which helps assess the efficiency and aging of the battery system.
   Battery Power Output Capability PID: Indicates the maximum power the battery can safely deliver based on its current state of charge, temperature, and health.

Once relevant information is obtained, DTC OBD-II data 156, OBD-II live data 160, DTC OEM data 164 and OEM live data 168 is sent to cloud server 144 via network cloud 148. This information, along with that of initial battery result 140, provided for enhanced battery health monitoring determination as detailed below. A resultant final battery health result 172 is relayed to a user, suitably via a data device such as tablet or smartphone 176.

Integrating this diagnostic process into an AI/ML system involves collecting comprehensive data on battery measurements, including CCA, drop voltage, and crank voltage, along with OBD-II live data like voltage, current, temperature, and relevant DTCs. The system also incorporates OEM-specific data, such as cell voltages, state of charge, state of health, internal resistance, and cooling metrics. Feature engineering is performed to extract trends, correlations, and deviations from normal values, focusing on battery-related parameters. A supervised machine learning model is then trained on this dataset, with outcomes labeled as PASS, MARGINAL, or FAIL based on historical battery health outcomes and known failure patterns.

Time-series models like LSTMs (Long short-Term Memory) or other suitable Recurrent Neural Networks are suitably utilized to track changes in battery parameters over time and predict potential failures before they occur. The system employs an ensemble approach by combining multiple models: classification models to determine pass, marginal or fail status based on static conditions, anomaly detection models to flag unexpected deviations, and regression models to predict remaining battery lifespan and time-to-failure.

A feedback loop continuously updates the machine learning models with new battery data, allowing the system to adapt to evolving vehicle technologies and emerging issues. The AI/ML system is deployed either in the cloud or on-board the vehicle, enabling real-time diagnostics. When a battery health test is conducted, the system collects all baseline and additional data, processes it through the trained models, and delivers a final result based on the aggregated analysis. Marginal conditions trigger specific follow-up actions, and predictive alerts are generated for proactive maintenance.

This AI/ML integration provides accurate, dynamic, and predictive diagnostics, allowing for precise detection of battery health status, identification of emerging issues, and timely interventions to prevent failures. The system is designed to continuously learn and improve, ensuring that it remains effective even as new data and patterns emerge.

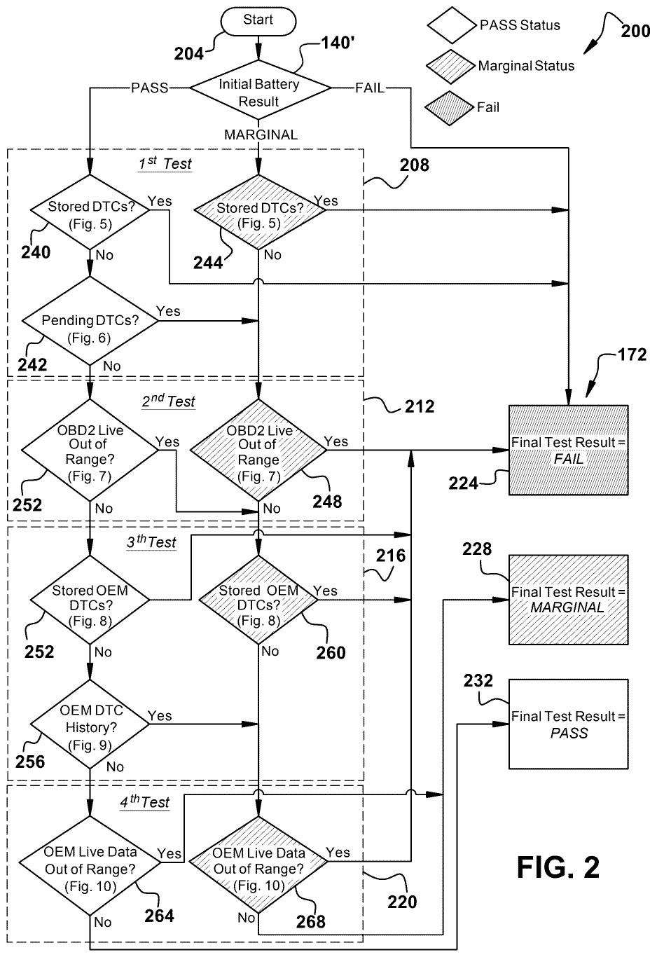

FIG. 2 illustrates a flow chart 200 for an example embodiment of a system for determining a health status of a vehicle battery. The process commences at block 204 where an initial battery result 140′ is received from a battery tester. Such information may include a CCA value, drop voltage and a crank voltage. Initial battery result information may also include tester-supplied information, such as a measured voltage or conductance. Battery status from a battery tester is categorized as PASS, MARGINAL or FAIL. For measured battery voltage in vehicles, a typical cutoff range can help distinguish between marginal and fail conditions when readings fall outside the normal operating range of around 12.5 to 14.5 volts. If the voltage is between 11.5 and 12.4 volts or between 14.6 and 15.0 volts, this may be considered a marginal out-of-range condition. These values suggest minor issues such as slight battery depletion, early signs of alternator strain, or weak charging cycles. While these readings are slightly outside the optimal range, they may not indicate an immediate problem but could benefit from further monitoring.

However, when the voltage drops below 11.5 volts or rises above 15.0 volts, this is typically considered a fail out-of-range condition. Readings below 11.5 volts indicate a significant under-voltage condition, which could suggest a failing battery or a severe issue with the charging system. Similarly, readings above 15.0 volts indicate potential overcharging, which could damage the battery or other electrical components, possibly due to a faulty voltage regulator or alternator. These fail-level readings usually require immediate attention to prevent damage and ensure vehicle reliability.

In the illustrated example embodiment, battery health is determined by a sequence of four tests. First test 208 is taken relative to standard OBD DTC data. Second test 212 is taken relative to standard OBD live data. Third test 216 is taken relative to OEM DTC data. Fourth test 220 is taken relative to OEM live data. A final result of this testing sequence is one of FAIL at block 224, MARGINAL at block 228 or PASS at block 232. While initial battery result is set for PASS, MARGINAL or FAIL, the status may change during the testing sequence. Blocks with light shading 234 indicate a current test status as PASS and blocks with intermediate shading 236 indicate a current test status of MARGINAL. Dark shading 238 is indicative of a test FAIL status at block 224.

DTCs that suggest a marginal determination often signal early signs of issues without indicating immediate failure. Codes such as P0562 (System Voltage Low) and P0563 (System Voltage High) point to slight deviations in system voltage, which may reflect minor undercharging or overcharging. Other codes, like P0621 and P0622, indicate potential issues in the generator's control circuits that could reduce charging efficiency without full failure, while P2503 and P2504 suggest slightly low or high charging system voltage. These marginal codes flag conditions that, while not critical, could worsen over time and warrant monitoring to prevent progression into more severe faults.

DTCs indicating a battery fail condition point to critical faults in the battery or charging system that need immediate attention. Codes like P0562 (System Voltage Low) and P0563 (System Voltage High) reveal severe undercharging or overcharging issues, which can quickly damage the battery or electrical components. P0620 and P0621 indicate faults in the alternator's control or warning circuits, potentially causing the battery to receive no charge. P2503 (Charging System Voltage Low) and P2504 (Charging System Voltage High) similarly suggest dangerous undercharging or overcharging conditions due to malfunctioning components. These DTCs collectively signal failures that, if unaddressed, can lead to complete battery failure and damage to vehicle electronics.

Conventional battery tester result a PASS status when the battery is still problematic. A battery tester might conclude that a battery has passed based on specific metrics, such as Cold Cranking Amps (CCA), voltage, and charge level, which could appear within acceptable ranges during the test. However, associated DTC information indicating a fail may reveal deeper or intermittent issues in the vehicle's charging system or electrical environment that the battery tester does not directly assess. Here are some reasons why this discrepancy could occur:
Intermittent Charging System Issues: DTCs might capture issues with the alternator or voltage regulator, such as undercharging or overcharging, that only happen periodically. A battery tester measures the battery in its current state but doesn't account for charging inconsistencies over time, which could degrade the battery more quickly than the tester results suggest.
Transient Electrical Faults: Diagnostic codes may flag transient faults in the vehicle's electrical system, like occasional low or high voltage spikes, that don't affect the battery's immediate ability to start the vehicle but could shorten its lifespan. These faults might not show up in a one-time battery test.
Temperature or Load Effects: DTCs might indicate issues when the battery is exposed to high or low temperatures or under heavy loads, which a stationary tester may not simulate. This could lead to passing results from the tester in controlled conditions, while real-world operating conditions reveal fail-level issues.
Historical DTCs and Recent Repairs: History codes may point to past issues, like overcharging events, that have already weakened the battery, even if it tests within range now. Recent fixes to the charging system might temporarily mask underlying wear or damage to the battery, which could still lead to failure.
Voltage vs. Capacity Assessment: A battery tester might detect sufficient voltage, but DTCs could reveal insufficient charging capacity over time, such as with P0620 (Generator Control Circuit Malfunction). The tester might not measure the battery's ability to hold a charge under real-world use, leading to a passing grade despite a compromised system.

In summary, while a battery tester evaluates the immediate health of the battery based on current performance, DTC information can reveal underlying or intermittent issues in the vehicle's charging or electrical system that may not manifest during a single, static test but still impact long-term battery health.

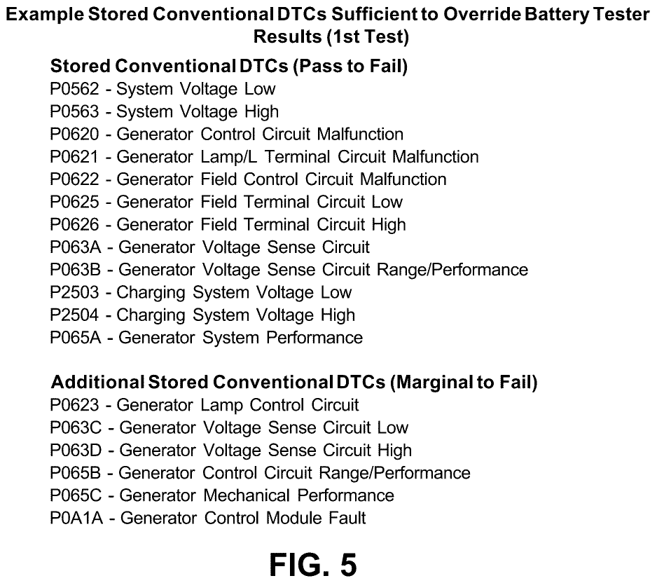

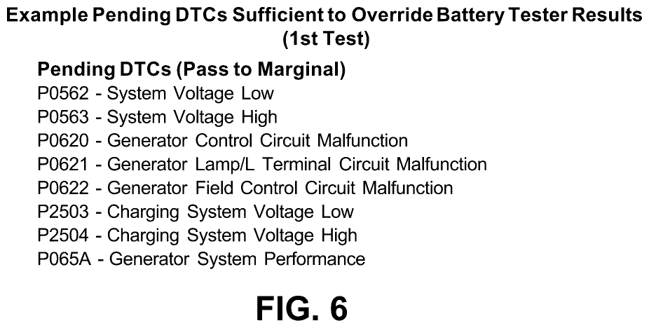

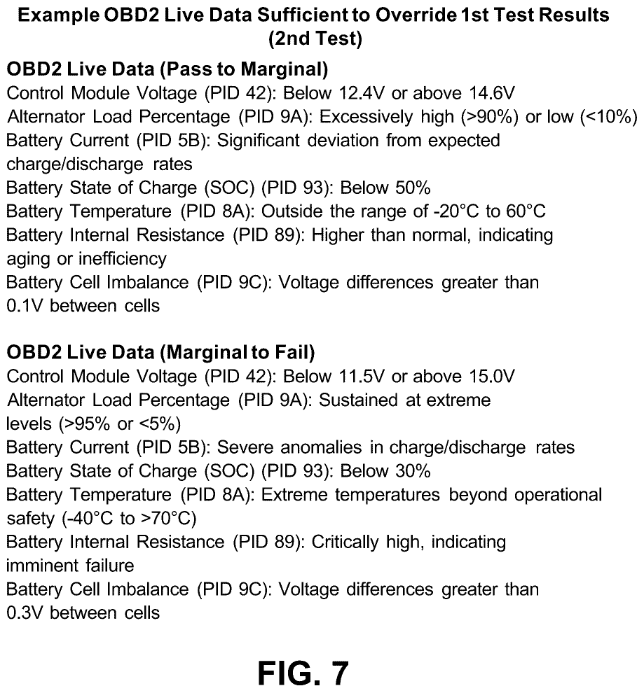

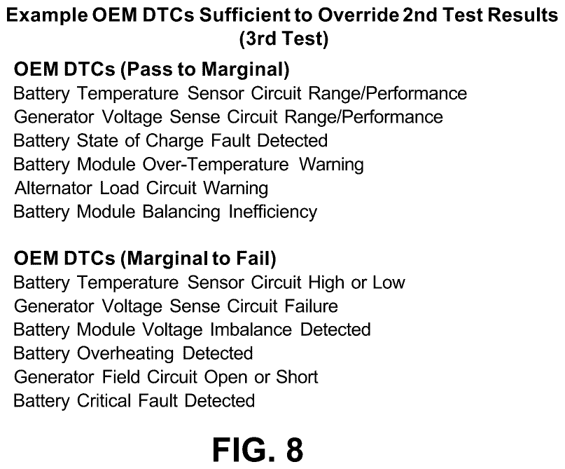

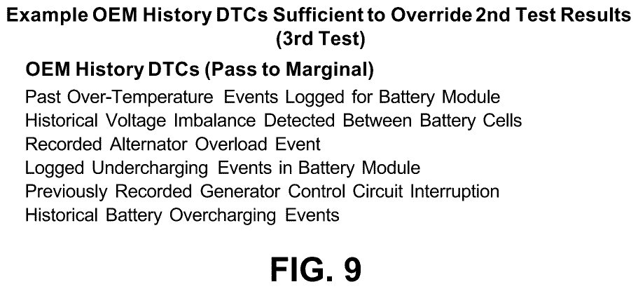

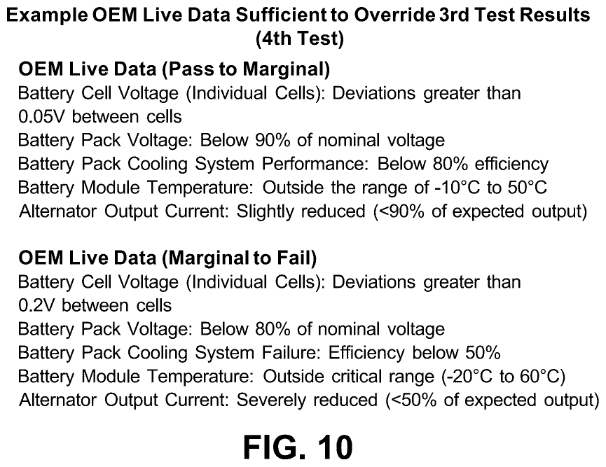

In the illustrated example of FIG. 2, an initial battery test result 140′ of FAIL indicates that no further testing is require and the system proceeds to FAIL block 224. It is to be noted that when a final battery health status is reached, OBD data including DTCs, live data, OEM DTCs and OEM live data relative to battery health determination are still collected and available for further review and machine learning input for future analyses. The illustrated example embodiment is comprised of four tests: First test 208 applies stored and pending DTC results to initial battery result 104′. Example DTCs are listed in FIGS. 5 and 6. Second test 212 applies OBD live data results to a result of first test 208. Example OBD live date is listed in FIG. 7. Third test 216 applies stored and history OEM DTC results to a result of second test 212. Example stored and history OEM DTCs are listed in FIGS. 8 and 9. Fourth test 220 applies OEM live data results to a result of third test 216. Example OEM live data is listed in FIG. 10. The battery is result is either FAIL 224, MARGINAL 228 or PASS 232.

A result of PASS or MARGINAL from battery test result 140′ results in progress to first test 208 relative to standard DTCs. The PASS result causes progress to block 240 where a test for DTCs is made. If DTCs are present, the system ends with a FAIL at block 224. If no DTCs are present, a test is made at block 242 as to whether pending DTCs are present. If so, the status is changed from PASS to MARGINAL before entering second test 212. If no pending DTCs are present, the PASS status is maintained before entering second test 212. If battery test result 140′ is MARGINAL, the system progresses to block 244 where a determined presence of stored DTCs leads to FAIL status block 224. If no DTCs are present, the system progresses to second test 212.

If entry into second test 212 is with a current PASS status from block 242, a test as to whether OBD-II live data is out of range at block 246. If so, the current status is changed to MARGINAL before entry into third test 216. If not, PASS status is maintained before progressing into third test 216. If entry into second test 212 is with a current MARGINAL status from block 244, a test as to whether OBD-II live data is out of range is made at block 248. If so, the system proceeds with a FAIL determination at block 224. If no OBD-II live data is out of range at block 248, the system proceeds to third test 216.

If entry into third test 216 is with a current PASS status from block 246, a test for stored OEM DTCs is made at block 252. If they are present, the system proceeds to a final FAIL determination at block 224. If no OEM DTCs are stored, a test is made as to whether OEM history data is stored at block 256. If so, the current status is changed to MARGINAL before entry into fourth test 220. If entry into third test 216 is with a current MARGINAL status from block 248, a test is made for stored OEM DTCs at block 260. If they are present, the system proceeds to a final FAIL determination at block 224. If no stored OEM DTCs are present, the system proceeds to fourth test 220.

If entry into fourth test 220 is with a current status of PASS from block 256, a test is made at block 264 as to whether OEM live data is out of range. If so, a final test result of MARGINAL is set at block 228. If not, a final test result of PASS is set at block 232. If entry into fourth test 220 is with a current status of MARGINAL from block 260, a test is made at block 268 to determine if OEM live data is out of range. If so, a final test result of FAIL is set at block 224. If not, a final test result of MARGINAL is set at block 228.

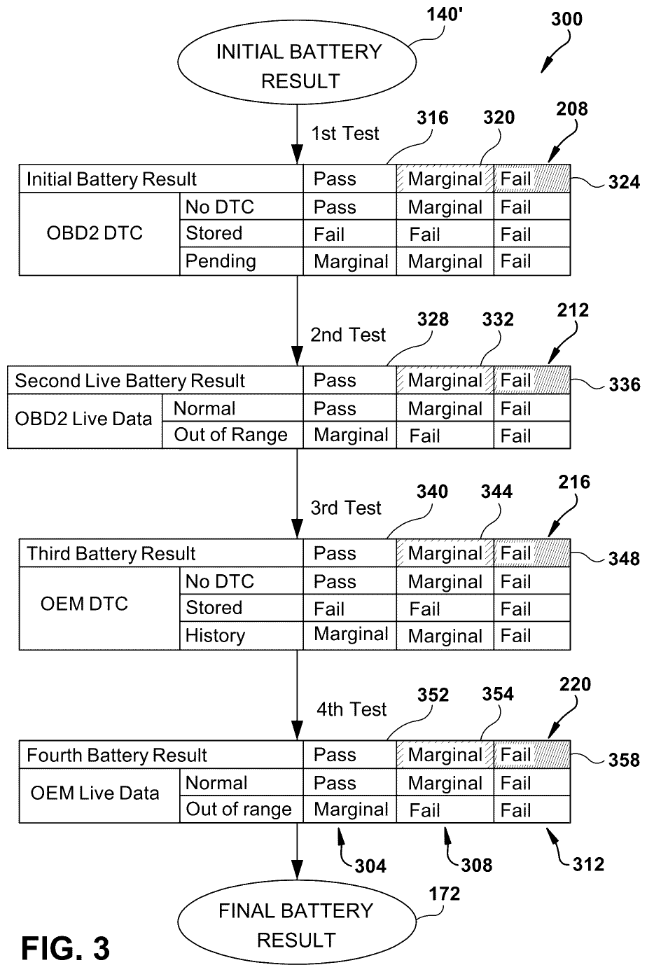

FIG. 3 shows a flow diagram 300 corresponding to the flowchart of FIG. 2. Initial battery result 140′ is passed through the sequence of four tests, first test 208, second test 212, third test 216 and fourth test 220, resulting in final battery result 172. In this illustration, each test includes a pass column 304, a marginal column 308 and a fail column 312. First test 208 receives a result of either PASS 316, MARGINAL 320 or FAIL 324 from initial battery result 140′. OBD DTC data is applied as illustrated above, modifying the initial battery result with a first test result of PASS, MARGINAL or FAIL. It is to be noted, once a FAIL has been determined, that will be the ultimate result.

Second test 212 receives a determination of PASS 328, MARGINAL 332 or FAIL 336 from first test 208 and applies OBD-II live data as illustrated above, modifying the first test result with a second test result of PASS, MARGINAL or FAIL.

Third test 216 receives a determination of PASS 340, MARGINAL 344 or FAIL 348 from second test 212, and applies OEM DTC data as illustrated above, modifying the second test result with third test result of PASS, MARGINAL or FAIL.

Fourth test 220 receives a determination of PASS 352, MARGINAL 356 or FAIL 358 from third test 216, and applies OBD live data as illustrated above, modifying the third test result with a final battery test result of PASS, MARGINAL or FAIL.

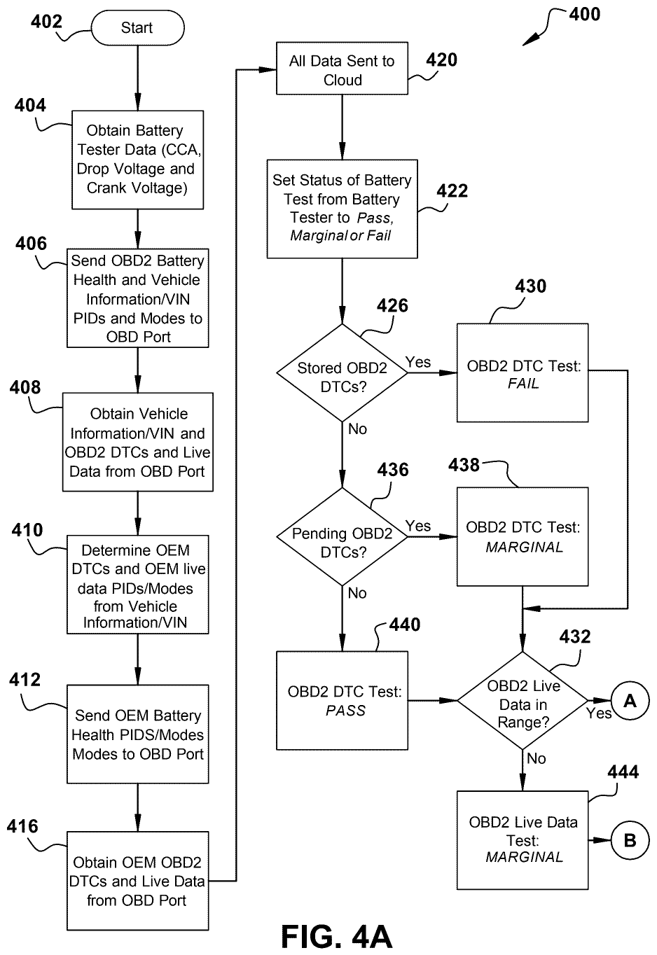

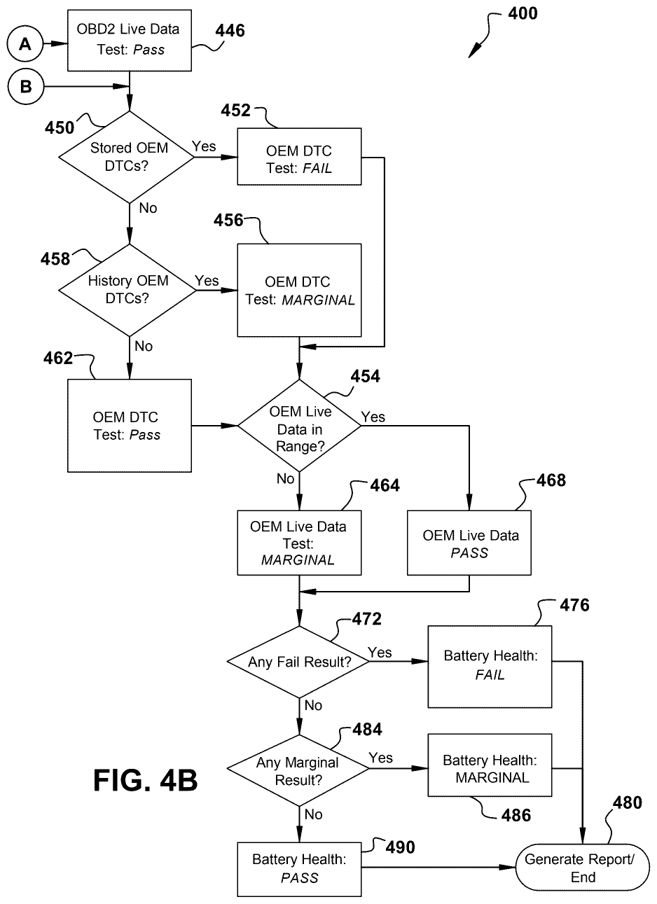

FIGS. 4A and 4B illustrate a flowchart 400 of another example embodiment of a system for determining battery health status. The process commences at block 402 and proceeds to block 404 where a battery tester is connected to a vehicle battery and measured values obtained. Values may include CCAs, drop voltage, crank voltage, etc. Next, OBD PIDs and modes associated with vehicle information, such as a VIN, as well as battery health information is sent to a vehicle OBD-II port at block 406. Responsive thereto, vehicle and VIN information, OBD-II DTCs and live data are obtained at block 408. The vehicle/VIN information provides for identification of the vehicle and a determination as to OEM OBD and live data that is obtainable in block 410. OEM information PIDs and modes are then sent to the OBD port at block 412, and OEM DTCs and live data are received responsive thereto at block 416.

All data is suitably sent to a cloud server at block 420 for determination of battery health. An initial battery status is established from the battery tester data at block 422, and set as PASS, MARGINAL or FAIL based on these test results. If stored battery health DTCs are found at block 426, the OBD-II DTC test is set to FAIL at block 430 before proceeding to the next test at block 432. If there are no OBD-II DTCs at block 426, a test is made at block 436 to determine if any pending battery health related DTCs exist. If so, the OBD-II DTC test status is set to MARGINAL at block 438 before proceeding to the live data test at block 432. If it is determined at block 436 that there are also no pending OBD-II DTCs, the test status is set to PASS at block 440 before proceeding to block 432.

A test is made of OBD-II live data at block 432 to determine whether it is a range of acceptability. If not, the OBD-II live data test is set to MARGINAL at block 444 for the next test at block 450. If the live data is in range, the test is set to PASS at block 446 before proceeding to the next test at block 450.

A determination is made at block 450 as to whether there are stored OEM OBD-II DTCs. If so, the test is set to FAIL at block 452 before proceeding to the next test at block 452. If no OEM DTCs are found at block 450, a test for history OEM OB-II DTCs is made at block 458. If present, the test is set as MARGINAL at block 456 before proceeding to block 454. If there are now history DTCs present at block 458, the test is set to PASS at block 462 before proceeding to block 454.

A test as to whether OEM OBD-II live data is in range is made at block 454. If so, the test result is set to MARGINAL at block 464 before proceeding to block 472. If all OEM OBD-II live data is within an acceptable range, the test result is set to PASS at block 468 before proceeding to block 472.

A test is made at block 472 to determine if any testing resulted in FAIL. If so, the battery health test is set to FAIL at block 476. A report is then generated the system terminates at block 480. If there is no FAIL result at block 472, a determination is made as to whether any test result was MARGINAL at block 484. If so, the battery health test is set to MARGINAL at block 486 before proceeding to block 480. If there is no MARGINAL result, the battery health is set to PASS at block 490 before proceeding to block 480.

When OBD live data is determined to be out of range, it is often possible to measure and analyze how far out of range the data is. Live data values are typically read in real-time and compared to a set of predefined acceptable ranges or thresholds established by the vehicle manufacturer or diagnostic system.

For example, if the battery voltage is expected to stay within 12.5 to 14.5 volts under normal operating conditions, but the live data reads 11.8 volts or 15.2 volts, it's not only clear that the voltage is out of range but also exactly how much it deviates from the expected range. This level of detail allows for more precise diagnostics, as minor deviations might suggest a temporary issue or minor inefficiency, while larger deviations may indicate a more serious fault, like a failing alternator or battery. In a modified embodiment, determinations of MARGINAL include a determination as to a degree to which the live data is out of range. When multiple determinations of MARGINAL have been made, a secondary test as to how far each may be out of range to determine overall battery health. By way of particular example, two MARGINAL results that are only slightly out of range may be acceptable individually. But if those results are substantially out of range, the cumulative effect moves the overall battery health from MARGINAL to fail.

By way of particular example, or battery voltage in vehicles, a typical cutoff range can help distinguish between marginal and fail conditions when readings fall outside the normal operating range of around 12.5 to 14.5 volts. If the voltage is between 11.5 and 12.4 volts or between 14.6 and 15.0 volts, this may be considered a marginal out-of-range condition. These values suggest minor issues such as slight battery depletion, early signs of alternator strain, or weak charging cycles. While these readings are slightly outside the optimal range, they may not indicate an immediate problem but could benefit from further monitoring.

However, when the voltage drops below 11.5 volts or rises above 15.0 volts, this is typically considered a fail out-of-range condition. Readings below 11.5 volts indicate a significant under-voltage condition, which could suggest a failing battery or a severe issue with the charging system. Similarly, readings above 15.0 volts indicate potential overcharging, which could damage the battery or other electrical components, possibly due to a faulty voltage regulator or alternator. These fail-level readings usually require immediate attention to prevent damage and ensure vehicle reliability.

FIG. 5 illustrates example conventional first test DTCs that may be applied to an initial battery test result to modify it from PASS to FAIL or from MARGINAL to FAIL. FIG. 6 illustrates example first test pending DTCs that may be sufficient to modify the initial battery results from PASS to MARGINAL.

FIG. 7 illustrates example second test OBD-II live information that may be applied to the first test result to modify it from PASS to MARGINAL or from MARGINAL to FAIL.

FIG. 8 illustrates example third test OEM DTCS that may be applied to the second test result to modify it from PASS to MARGINAL or from MARGINAL to FAIL. FIG. 9 illustrates example third test history DTCs that may be applied to the second test result to modify it from PASS to MARGINAL.

FIG. 10 illustrates example fourth test OEM live data that may be applied to the third test result to modify it from PASS to MARGINAL or from MARGINAL to FAIL. The result of the fourth test becomes the final battery health test result as detailed above.

The above description is given by way of example, and not limitation. Given the above disclosure, one skilled in the art could devise variations that are within the scope and spirit of the invention disclosed herein. Further, the various features of the embodiments disclosed herein can be used alone, or in varying combinations with each other and are not intended to be limited to the specific combination described herein. Thus, the scope of the claims is not to be limited by the illustrated embodiments.

1-14. (canceled)

15. A system for determining a battery health status of a vehicle battery, the system comprising:
a battery tester operable to perform a battery test on the vehicle battery; and
one or more servers configured to:
obtain a battery tester result of the battery test; determine a stored/pending status of one or more OBDS diagnostic trouble codes associated with faults in a battery temperature sensor circuit, generator control circuit, generator lamp circuit, generator field terminal circuit, generator voltage sensing circuit, generator system performance, or charging system voltage regulation;
determine whether the vehicle exhibits out of range OBDS live data received in response to one or more OBDS live data requests for control module voltage and alternator load percentage; and
determine the battery health status based on the battery test result, the stored/pending status of the one or more OBDS diagnostic codes, and an outcome of said determining whether the vehicle exhibits out of range OBDS live data;
wherein the one or more servers are further configured to determine a stored/pending status of one or more OEM diagnostic codes, said determining the battery health status being further based on the stored/pending status of the one or more OEM diagnostic codes.

16. (canceled)

17. The system of claim 15 wherein the one or more servers are further configured to determine whether the vehicle exhibits out of range OEM live data in response to one or more OEM live data requests, said determining the battery health status being further based on an outcome of said determining whether the vehicle exhibits out of range OEM live data.

18. A system for determining a battery health status of a vehicle battery, the system comprising:
a battery tester operable to perform a battery test on the vehicle battery; and
one or more servers configured to:
obtain a battery tester result of the battery test;
determine a stored/pending status of one or more OBDS diagnostic trouble codes associated with faults in a battery temperature sensor circuit, generator control circuit, generator lamp circuit, generator field terminal circuit, generator voltage sensing circuit, generator system performance, or charging system voltage regulation;
determine whether the vehicle exhibits out of range OBDS live data received in response to one or more OBDS live data requests for control module voltage and alternator load percentage; and
determine the battery health status based on the battery test result, the stored/pending status of the one or more OBDS diagnostic codes, and an outcome of said determining whether the vehicle exhibits out of range OBDS live data;
wherein the system further comprises a diagnostic tool operable to retrieve the stored/pending status of the one or more OBDS diagnostic codes from the vehicle, retrieve the OBDS live data responsive to the one or more OBDS live data requests, and wirelessly transmit the stored/pending status of the one or more OBDS diagnostic codes and the OBDS live data to the one or more servers.

19. The system of claim 18, wherein the diagnostic tool is operable to wirelessly transmit the stored/pending status of the one or more OBDS diagnostic codes and the OBDS live data to the one or more servers via a short range wireless connection with a mobile communication device.

20. The system of claim 15, wherein the battery tester is operable to wirelessly transmit the battery tester result to the one or more servers.

21. The system of claim 15, wherein the one or more servers are further configured to determine the one or more OEM diagnostic codes based on a vehicle identification number (VIN) of the vehicle.

22. The system of claim 17, wherein the one or more servers are further configured to determine the one or more OEM live data requests based on a vehicle identification number (VIN) of the vehicle.

23. The system of claim 17, wherein said determining whether the vehicle exhibits out of range OEM live data comprises inputting a response to the one or more OEM live data requests to a machine learning model.

24. The system of claim 15, wherein the battery tester result is based at least in part on a cold cranking amps (CCA) value measured by the battery tester.

25. The system of claim 15, wherein the battery health status comprises an indication of whether the vehicle battery is in a passing condition.

26. The system of claim 25, wherein the battery health status further comprises an indication of a degree of the passing condition.

27. The system of claim 18, wherein the battery tester result is based at least in part on a cold cranking amps (CCA) value measured by the battery tester.

28. The system of claim 18, wherein the battery health status comprises an indication of whether the vehicle battery is in a passing condition.

29. The system of claim 28, wherein the battery health status further comprises an indication of a degree of the passing condition.

30. A system for determining a battery health status of a vehicle battery, the system comprising:
a battery tester operable to perform a battery test on the vehicle battery; and
one or more servers configured to:
obtain a battery tester result of the battery test;
determine a stored/pending status of one or more OBDS diagnostic trouble codes associated with faults in a battery temperature sensor circuit, generator control circuit, generator lamp circuit, generator field terminal circuit, generator voltage sensing circuit, generator system performance, or charging system voltage regulation;
determine whether the vehicle exhibits out of range OBDS live data received in response to one or more OBDS live data requests for control module voltage and alternator load percentage; and
determine the battery health status based on the battery test result, the stored/pending status of the one or more OBDS diagnostic codes, and an outcome of said determining whether the vehicle exhibits out of range OBDS live data;
wherein said determining whether the vehicle exhibits out of range OBDS live data comprises inputting a response to the one or more OBDS live data requests to a machine learning model.

31. The system of claim 30, further comprising a diagnostic tool operable to retrieve the stored/pending status of the one or more OBDS diagnostic codes from the vehicle, retrieve the OBDS live data responsive to the one or more OBDS live data requests, and wirelessly transmit the stored/pending status of the one or more OBDS diagnostic codes and the OBDS live data to the one or more servers.

32. The system of claim 30, wherein the battery tester result is based at least in part on a cold cranking amps (CCA) value measured by the battery tester.

33. A system for determining a battery health status of a vehicle battery, the system comprising:
a battery tester operable to perform a battery test on the vehicle battery; and
one or more servers configured to:
obtain a battery tester result of the battery test;
determine a stored/pending status of one or more OBDS diagnostic trouble codes associated with faults in a battery temperature sensor circuit, generator control circuit, generator lamp circuit, generator field terminal circuit, generator voltage sensing circuit, generator system performance, or charging system voltage regulation;
determine whether the vehicle exhibits out of range OBDS live data received in response to one or more OBDS live data requests for control module voltage and alternator load percentage; and
determine the battery health status based on the battery test result, the stored/pending status of the one or more OBDS diagnostic codes, and an outcome of said determining whether the vehicle exhibits out of range OBDS live data;
wherein said determining the battery health status comprises inputting the battery test result, the stored/pending status of the one or more OBDS diagnostic codes, and the outcome of said determining whether the vehicle exhibits out of range OBDS live data to a machine learning model.

34. The system of claim 33, further comprising a diagnostic tool operable to retrieve the stored/pending status of the one or more OBDS diagnostic codes from the vehicle, retrieve the OBDS live data responsive to the one or more OBDS live data requests, and wirelessly transmit the stored/pending status of the one or more OBDS diagnostic codes and the OBDS live data to the one or more servers.

35. The system of claim 33, wherein the battery tester result is based at least in part on a cold cranking amps (CCA) value measured by the battery tester.
